(19) United States
(12) Patent Application Publication
(10) Pub. No.: US 2023/0180370 A1
(43) Pub. Date: Jun. 8, 2023

(54) A CONTROL SYSTEM FOR CONTROLLING A COOLING FAN

(71) Applicant: SIGNIFY HOLDING B.V., EINDHOVEN (NL)

(72) Inventors: FETZE PIJLMAN, EINDHOVEN (NL); JAN DE GRAAF, UDEN (NL)

(21) Appl. No.: 17/911,695

(22) PCT Filed: Mar. 15, 2021
(86) PCT No.: PCT/EP2021/056467

§ 371 Date: Sep. 15, 2022

(30) Foreign Application Priority Data
Mar. 17, 2020 (EP) 20163564.6

(51) Int. Cl. H05B 47/115; F21V 29/60; F21V 23/04; H05K 7/20; H05B 45/10; H05B 45/56

(52) U.S. Cl. CPC H05B 47/115; F21V 29/60; F21V 23/0471; H05K 7/20209; H05B 45/10; H05B 45/56; F21S 8/086

(57) ABSTRACT

Some embodiments are directed to a control system (140, 141, 142) for controlling a cooling fan used together with a motion detector. The controlling comprises controlling an activation and/or a rotation frequency of the cooling fan. The control system has a communication interface arranged for communication with the motion detector. The motion detector is configured to detect motion by emitting and receiving electromagnetic radiation and establishing frequency differences between the emitted and received electromagnetic radiation. The system operates the cooling fan at a regular rotation frequency and then, in response to obtaining a signal indicating that the motion detector is being used, adjusts the activation and/or the rotation frequency of the cooling fan, wherein said adjustment reduces an interference of the cooling fan with the frequency differences established by the motion detector.

### FIELD OF THE INVENTION

The invention relates to a luminaire and a lamp in which a control system for controlling a cooling fan is integrated. The invention further relates to a method of controlling a cooling fan; and to a computer readable medium.

### BACKGROUND OF THE INVENTION

Reliable motion detection is important in a number of fields. For example, motion detection is used in lighting systems to control the lighting. Using a motion detector it can be avoided that lights are turned on when no persons are present. Other applications are, e.g., in burglar alarms, and office occupancy detection, e.g., for office management.

Motion detectors based on microwave radiation are becoming increasingly popular for motion sensing. Such sensors rely on the Doppler effect, emitting and receiving electromagnetic radiation and establishing a frequency difference between the emitted and received electromagnetic radiation. Besides motion, such sensors may also be able to measure speed, direction of motion, and sometimes also distance. A network of such sensors can enable tracking which makes them of value.

Motion detectors are often integrated into luminaires, which is convenient since luminaires anyway need to be installed, for example, in houses, offices, factories, or other types of buildings. By integrating motion detectors into luminaires, motion detection can be enabled at low cost and with low effort.

A known motion detector is described in Korean patent application KR20160141503, “APPARATUS AND METHOD FOR DRIVING LIGHT”. In the Korean patent application a lighting driving device is disclosed for driving a lighting device equipped with a motion sensing part. The device automatically controls lighting depending on whether motion is detected or not.

WO98/35846A2 discloses a system for cut-off of fans or blowers in a car so that air streams do not interfere with signal sensing by sensors present in the car. The system employs ultrasound sensing to determine the intrusion, or imminence of intrusion, into a predefined zone between the instrument panel and the occupant seat. In case such intrusion is detected, the automotive air bag system may be activated. In addition, the fans or blowers may be switched off in order to prevent that the air flow interferes with signal transmittal or reception.

A known problem of motion detectors that use microwave radiation, is their sensitivity to electronic and mechanical noise. Mechanical vibrations somehow can lead to strong electronic frequency components. Similarly, electronic noise of various sources, e.g. ZigBee radio, can lead to noise in the received microwave radiation. Such noise, if not handled properly, can lead to faulty behavior of the sensor, meaning that false positives or false negatives may be generated. It is known to solve such issues by providing electromagnetic shielding between the sensor and close by electronic noise sources.

### SUMMARY OF THE INVENTION

In various cases, it is desirable to operate a motion detector in the same area as, e.g., closely to, a cooling fan. For example, this can be the case when integrating a motion detector into a luminaire. Various types of luminaires or lamps, for example, high bay light fixtures or LED HID (high intensity discharge) replacement lamps, are equipped with fans for cooling the lamp in operation. It would be desirable to integrate a motion detector into such a luminaire or lamp with a built-in cooling fan. However, such integration is problematic because the fan produces electronic/mechanical noise that can affect the motion detection. Specifically, false positives may be generated because the motion detector mistakes the noise produced by the fan for an actual movement, or it may be needed to operate the motion detector at a lower sensitivity to prevent such false positives, thereby degrading the sensing performance.

To address these and other problems, in an aspect, a luminaire is proposed comprising a control system, a cooling fan, and optionally a motion detector, wherein the cooling fan is arranged to cool a light-emitting element connectable to or integrated in the luminaire, and wherein a control system is arranged for controlling a cooling fan. The cooling fan is used together with a motion detector, e.g., the two operate in the same room or within a certain distance of each other, say one meter or ten centimeters. The cooling fan may be an electronics cooling fan configured for cooling of a particular device such as a light-emitting element, but can for example also be a ceiling fan used to cool the room it is installed in. The motion detector is configured to detect motion by emitting and receiving electromagnetic radiation and establishing frequency differences between the emitted and received electromagnetic radiation.

In a further aspect, a lamp is provided, connectable to a luminaire and comprising a control system, a cooling fan, optionally a motion detector, and a light-emitting element; wherein the cooling fan is arranged to cool the light-emitting element, and wherein the control system is arranged for controlling the cooling fan, said controlling comprising controlling an activation and/or a rotation frequency of the cooling fan, the control system comprising a communication interface arranged for communication with the motion detector, the motion detector being configured to detect motion by emitting and receiving electromagnetic radiation and establishing frequency differences between the emitted and received electromagnetic radiation, a processor subsystem configured to operate the cooling fan at a rotation frequency, obtain a signal indicative of the motion detector being used to detect motion, in response to said signal indicating that the motion detector is being used, adjust the activation and/or the rotation frequency of the cooling fan, wherein said adjustment reduces an interference of the cooling fan with the frequency differences established by the motion detector.

At some point, the control system operates the cooling fan at a regular rotation frequency. Driving the cooling fan at the regular rotation frequency may cause a degree of interference with the motion detector, for example, noise may be generated within a range of frequency differences that the motion detector is configured to measure. For example, this noise may lead to false positives, or to a decreased sensitivity due to the motion detector being configured to ignore the noise.

Interestingly, control systems as described herein control the fan based on a signal indicating whether or not the motion detector is being used to detect motion. In response to learning that the motion detector is being used to detect motion, the control system adjusts the activation and/or the rotation frequency of the cooling fan. Accordingly, interference of the cooling fan with the frequency differences established by the motion detector is reduced. Accordingly, the operation of the motion detector is improved, e.g., the false positive rate of the motion detector is decreased and/or the motion detector can operate at a higher sensitivity.

For example, the control system may receive the motion detector activity signal from the motion detector, or the control system itself may be further configured to control the motion detector and accordingly generate this signal itself. In both cases, the control system may be arranged for communication with the motion detector to receive activity signals and/or to send control signals.

For example, to reduce the interference, the cooling fan may be temporarily deactivated, or its rotation frequency may be temporarily increased. Deactivating the cooling fan is an effective measure for reducing interference, but is preferably performed only temporarily, e.g., during a relatively short time window in which the motion detector is active. This way, risk of overheating is reduced. Deactivating the cooling fan can also be combined with other measures, such as dimming a light-emitting element that is being cooled or, more generally, operating a device being cooled by the cooling fan in a modus that generates less heat.

Deactivating the cooling fan does not necessarily mean that the cooling fan stops spinning, e.g., driving of the cooling fan may be deactivated but the cooling fan may continue to rotate for some time. Indeed, a significant part or even most of the interference may be caused by electronic or mechanical noise due to driving the cooling fan, not due to the actual rotation or air displacement of the cooling fan itself. By not actively preventing the cooling fan from spinning, the cooling fan may be allowed to still provide cooling as long as it keeps spinning. The fan may even continue to spin during the whole time the cooling fan is temporarily deactivated.

Interference may also be reduced by increasing the rotation frequency of the cooling fan. Generally, the rotation frequency may be increased to a value above the range of frequency differences that the motion detector is configured to establish. Indeed, at least some degree of interference may be expected to take place at the rotation frequency, and interference can thus be reduced if the rotation frequency is not in the range of the motion detector. However, there is not always such a direct correspondence between the rotation frequency of the cooling fan and the frequencies at which the cooling fan causes noise. Accordingly, it is also possible to determine empirically which rotation frequencies are used to reduce interference, for example, by monitoring the noise level for various rotation frequencies or similar. Generally, increasing the rotation frequency only temporarily means that at other times, the cooling fan can still be operated at regular rotation frequencies, which has various advantages, including improving the lifetime of the fan by reducing wear and tear (and thus enabling cheaper fans to be used); reducing power consumption and reducing audible noise being generated by the fan.

Increasing the rotation frequency can even more effectively reduce noise if the operation of the motion detector is being taken into account. For example, in various motion detectors, a low-pass filter is applied to a signal representing the frequency differences between the emitted and received electromagnetic radiation. By increasing the rotation frequency to at least the cut-off frequency of the low-pass filter, and preferably to within a stopband of the low-pass filter, it can be effectively avoided that the motion detector detects this frequency. Various motion detectors also, at some point, perform sampling of a signal representing the frequency differences. In such cases, a beneficial choice for the increased fan rotation frequency that can be used instead or in addition, is to select this frequency to be an integer fraction multiple of the Nyquist frequency. This may result in the rotation frequency, or its multiples, corresponding to a zero frequency when sampling, which frequency may then be ignored by the motion detector.

Another way to reduce interference with frequency differences established by the motion detector, is by adjusting the rotation frequency of the cooling fan according to a periodic waveform, at least when the motion detector is active. The motion detector can then filter out frequency differences that vary according to the period waveform. Accordingly, the cooling fan and the motion detector may act in sync with each other to ensure that the motion detector filters out the right frequency differences at the right time. To this end, the signal indicative of the motion detector being used to detect motion, as received or generated by the fan control system, may indicate not only that the motion detector is being used, but also the rotation frequency to be used by the fan and to be ignored by the motion detector.

As mentioned, a noise peak may be expected at the rotation frequency itself, which can accordingly be filtered out by the motion detector based on the rotation frequency that the cooling fan is currently rotating at. However, noise may also occur at other frequencies. Still, also such noise at other frequencies may be expected to vary according to the periodic waveform, e.g., at least with the same period and/or phase. Accordingly, also this noise can be filtered out by the motion detector. For example, filtering out may mean measuring with less sensitivity at the corresponding frequencies, e.g., applying a higher threshold to conclude that there is a motion.

By varying over time the rotation frequency and thus the frequencies at noise occurs, it can thus be avoided to always filter out the same frequencies. Accordingly, it may be avoided that certain movement speeds corresponding to these frequencies are always filtered out. Accordingly, such movement speeds can still be measured accurately, though possibly not at each moment in time.

Another specific example of adjusting the controlling of the cooling fan in response to a signal indicating that the motion detector is being used, is by alternating between moments at which the cooling fan is activated and the motion detector is deactivated; and moments at which the cooling fan is deactivated and the motion detector is activated. Accordingly, when motion sensing is needed, such sensing can be performed nearly continuously while also providing nearly continuous cooling. As also mentioned elsewhere, the cooling fan may be deactivated by deactivating the driving of the cooling fine while the cooling fan may be kept spinning, and accordingly, even during the motion detection the cooling fan may still provide cooling.

Different ways of adjusting the controlling the cooling fan can be supported by a control system and may be performed in a method, e.g., at some point in time the cooling fan may be temporarily deactivated, whereas at another point in time, the rotation frequency may be increased and/or varied according to a periodic waveform, etc.

In various embodiments, the motion detector may be used in lighting to control an activation of a light-emitting element. The fan may be used to cool the light-emitting element. A function of the motion detection may be to enable the light-emitting element when motion is detected. Typically, as long as the light-emitting element is disabled, the cooling fan is disabled as well.

The motion detector may then be used to disable the light-emitting element after a predefined period of not detecting motion. This predefined period is also known as the hold time. The hold time is typically reset when motion is detected. During a first part of this period, the fan may rotate at its regular rotation frequency. The motion detector may be operated during this first part of the period at a first sensitivity, that may be set relatively high to account for the noise caused by the cooling fan. Then, during a second part of the period, e.g., if no motion is detected during the first period, the activation and/or the rotation frequency of the fan may be adjusted as described herein. This may reduce interference with the motion detector, which may accordingly be configured to operate at a second, higher, sensitivity. If also during this second period no motion is detected, the light-emitting element may be disabled.

Thus, it can be avoided to have to adapt the fan operation during the first period, with the associated disadvantages of e.g. increasing the temperature of the luminaire or increasing the wear and tear of the fan. Still, because of the increased sensitivity in the second part of the predefined period, it may be avoided that the lights turn off while a motion takes place, e.g., while there is somebody in the room. In case the fan is disabled, the light-emitting element may be dimmed during part or all of the second period to reduce heat generation and thereby avoid overheating, e.g., based on temperature measurements of a temperature sensor.

Fan control systems as described herein may be advantageously employed as part of a lighting solution comprising a luminaire and a lamp connected or connectable to it. It is known to be advantageous to combine lights with motion detectors, e.g., to control the lighting based on the motion detector and/or to use the information from the motion detector for other applications, e.g., office management or burglary detection. The use of a fan control system as described herein allows the use of light-emitting elements that require cooling while still providing accurate motion sensing. Different deployment scenarios are possible. The control system can be part of the luminaire, together with the cooling fan and the motion detector. The control system can also, together with the motion detector and the fan, be part of a lamp connectable to a luminaire. There are other possibilities as well, e.g., to place the motion detector and the fan controller in the luminaire while putting the fan in the lamp, or the other way around. Various other ways of distributing the components will be envisaged by the skilled person.

Control systems, e.g., assemblies comprising a control system, a fan, and a motion detector, can however also be applied in various other settings apart from lighting. For example, such an assembly may be used in a smart pole, with motion detection information from the motion detector being transmitted using a wireless communication interface to an external data collection station. In such cases, the cooling fan may be used to cool the wireless communication interface. Although such a smart pole typically also comprises a light-emitting element, the light-emitting element may be located at a different place in the smart pole and may not require cooling by the cooling fan. Also other non-lighting-related applications are possible.

An embodiment of the method may be implemented on a computer as a computer implemented method, or in dedicated hardware, or in a combination of both. Executable code for an embodiment of the method may be stored on a computer program product. Examples of computer program products include memory devices, optical storage devices, integrated circuits, servers, online software, etc. Preferably, the computer program product comprises non-transitory program code stored on a computer readable medium for performing an embodiment of the method when said program product is executed on a computer.

In an embodiment, the computer program comprises computer program code adapted to perform all or part of the steps of an embodiment of the method when the computer program is run on a computer. Preferably, the computer program is embodied on a computer readable medium.

### BRIEF DESCRIPTION OF THE DRAWINGS

Further details, aspects, and embodiments of the invention will be described, by way of example only, with reference to the drawings. Elements in the figures are illustrated for simplicity and clarity and have not necessarily been drawn to scale. In the Figures, elements which correspond to elements already described may have the same reference numerals. In the drawings,

FIG. 1a schematically shows an example of an embodiment of a fan control system integrated into a lamp that is connectable to a luminaire,

FIG. 1b schematically shows an example of an embodiment of a fan control system integrated into a luminaire to which a lamp is connectable,

FIG. 1c schematically shows an example of an embodiment of a fan controller integrated into a smart pole,

FIG. 1d shows a bottom view of a luminaire according to an embodiment,

FIG. 1e shows a side view of a luminaire according to an embodiment,

FIG. 2 schematically shows an example of an embodiment of a motion detector,

FIG. 3a schematically shows an example of motion detector measurements with noise but no motion,

FIG. 3b schematically shows an example of motion detector measurements with motion,

FIG. 3c shows a scale for amplitudes of FIG. 3a and FIG. 3b,

FIG. 4 shows an example of controlling the a during a period of not detecting motion;

FIG. 5 shows examples of periodic waveforms according to which a rotation frequency of a cooling fan can be adjusted,

FIG. 6 schematically shows an example of an embodiment of a method of controlling a cooling fan;

FIG. 7 schematically shows a computer readable medium having a writable part comprising a computer program according to an embodiment,

FIG. 8 schematically shows a representation of a processor system according to an embodiment.

### LIST OF REFERENCE NUMERALS IN FIGS

100, 101, 102, 103 a luminaire
110, 111 a lamp
122 a lighting pole
132 a monitoring system
140, 141, 142 a control system
150, 151, 152, 153 a motion detector
160, 161, 162, 163 a cooling fan
170, 171, 173-1 . . . 8 a light-emitting element
182 a base station
200 a motion detector
211 a transmitter
212 a receiver
210 a signal generator
230 a mixer
250 a low-pass filter
260 a sampler
270 a frequency domain converter
280 a filter
281 established frequency differences
300 a frequency signal corresponding to noise
310 a frequency signal corresponding to motion
400 a predefined time period
410 a first part of the predefined time period
420 a second part of the predefined time period
510 a sinusoidal waveform
520 a triangular waveform
600 a fan controlling method
610 arranging communication
620 operating fan at regular rotation frequency
630 obtain signal indicative of motion detector being used to detect motion
635 signal indicates that motion detector is being used?
640 adjusting activation and/or rotation frequency of fan
1000 a computer readable medium
1010 a writable part
1020 a computer program
1100 a device
1110 a system bus
1120 a processor
1130 a memory
1140 a user interface
1150 a communication interface
1160 a storage
1161 an operating system
1162, 1163, 1164 instructions

### DETAILED DESCRIPTION OF EMBODIMENTS

While this invention is susceptible of embodiment in many different forms, there are shown in the drawings and will herein be described in detail one or more specific embodiments, with the understanding that the present disclosure is to be considered as exemplary of the principles of the invention and not intended to limit the invention to the specific embodiments shown and described.

In the following, for the sake of understanding, elements of embodiments are described in operation. However, it will be apparent that the respective elements are arranged to perform the functions being described as performed by them.

Further, the invention is not limited to the embodiments, and the invention lies in each and every novel feature or combination of features described herein or recited in mutually different dependent claims.

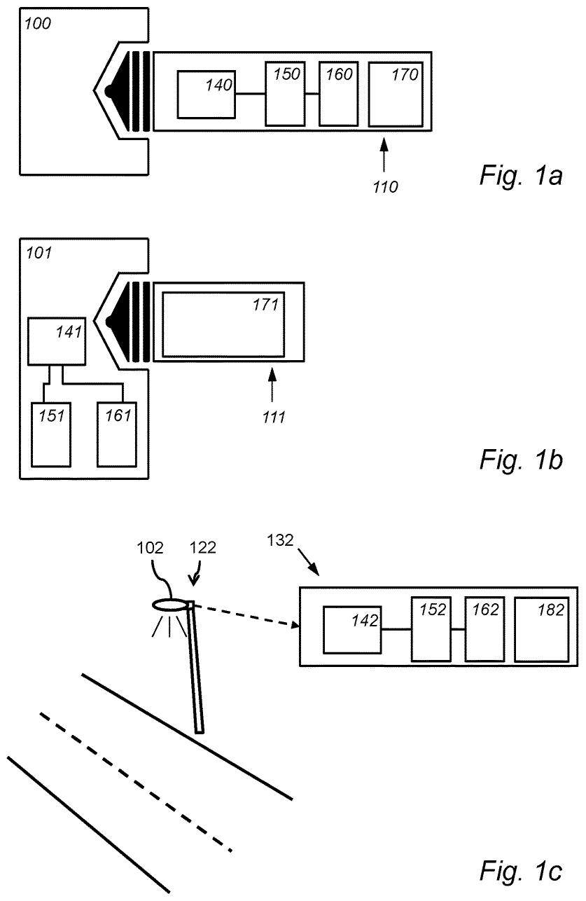

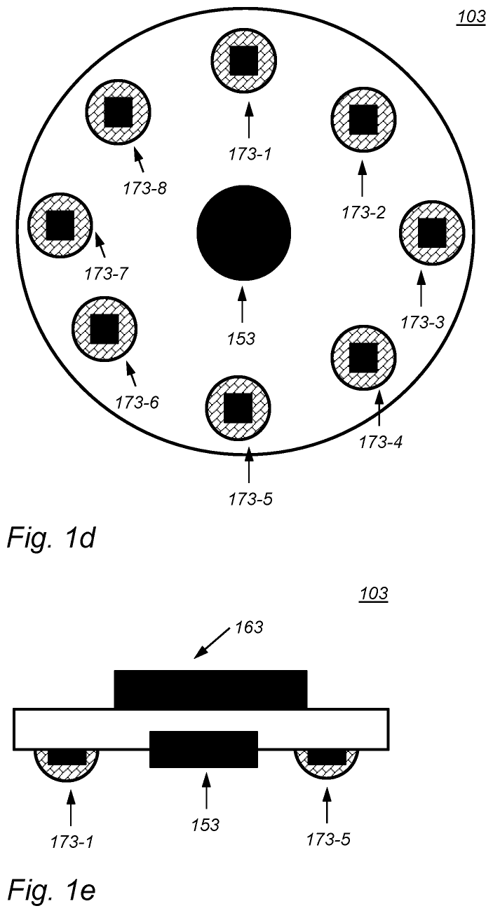

FIG. 1a schematically shows an example of an embodiment of a fan control system, in this case, integrated into a lamp.

The figure shows a lamp 110 that is connectable to a luminaire 100. Lamp 110 comprises a light-emitting element 170 requiring cooling. The cooling is provided by a cooling fan 160, which is controlled by a control system 140.

Lamp 110 may be a high-lumen LED lamp, such as a high-bay LED lamp or a LED High Intensity Discharge (HID) replacement lamp. Lamp 110 may be configured to operate at least 5000, at least 10000, or at least 15000 lumen, for example. The light-emitting element may comprise one or more light-emitting diodes (LEDs), for example, at least 100, at least 250, or at least 500 LEDs. High-lumen LED lamps may generate a significant amount of heat, requiring cooling by a fan. It is not required that the light-emitting element 170 is a LED though: any type of light-emitting element that requires cooling can be used.

Cooling fan 160 may be a conventional cooling fan. Cooling fan 160 may support various rotation frequencies, which, depending on the type, may or may not be dynamically adapted. For example, a cooling fan may support rotating at a regular rotation frequency of, e.g., at least 5 or at least 10 Hz and/or at most 50 or at most 100 Hz. For example, a normal rotation frequency may be 5000 rpm, or 83.3 Hz. The cooling fan may also support rotating at an increased rotation frequency, e.g., of at least 100 Hz, at least 150 Hz, or at least 200 Hz; usually, at most 250 Hz or 500 Hz.

The lamp 110 also comprises a motion detector 150. Motion detector 150 is configured to detect motion by emitting and receiving electromagnetic radiation and establishing frequency differences between the emitted and received electromagnetic radiation. Motion detector 150 may also be able to detect a speed (relative to the motion detector) and/or a distance of a detected moving object. Motion detector 150 may report information about detected objects, e.g., to control system 140 and/or to an external data collection device, e.g., for office management applications and the like. Various types of motion detectors, e.g., based on microwave radiation, are known per se. Examples of detecting motion are also provided throughout this specification.

Focusing now on the control system 140. Control system 140 controls the cooling fan 160. The controlling can involve controlling an activation (e.g., turning the fan on or off) and/or a rotation frequency of the cooling fan 160. Control system 140 may comprise a processor subsystem (not shown separately) by which the controlling may be implemented. The processor subsystem may be a processor circuit, examples of which are shown herein. For example, functions of the control system 140 may be wholly or partially implemented in computer instructions that are stored at the control system 140, e.g., in an electronic memory of system 140 and executable by a microprocessor of device 140. In hybrid embodiments, functional units are implemented partially in hardware, e.g., as coprocessors, e.g., signal coprocessors, and partially in software stored and executed on device 140.

Control system 140 may also comprise a control interface by means of which the cooling fan 160 can be controlled. This can be a conventional control interface. For example, control system 140 may control the cooling fan 160 by toggling whether or not power is provided to the cooling fan 160. In this case, the cooling fan 160 may be configured to operate at a constant rotation frequency.

Instead or in addition, control system 140 may be configured to control the cooling fan 160 by providing control signals, e.g., a control signal indicating a frequency at which the cooling fan 160 is to rotate. For example, cooling fan 160 may allow to control the rotation frequency of the cooling fan by varying the amount of voltage, and thereby current, supplied to the cooling fan. Cooling fan 160 may also allow to control the rotation frequency separately from the power supply by means of separate wires, e.g., a wire for controlling the rotation frequency and/or a wire for measuring the rotation frequency. Such wires typically allow analogue control signals; but digital is also possible.

Control system 140 can also provide control signals for controlling the cooling fan 160 wirelessly. For example, the cooling fan 160 may comprise a receiver configured to receive the control signals and adjust operation of the cooling fan accordingly. In any case, control system 140 is considered to control the cooling fan in the sense that it decides whether or not, and/or at what frequency, the cooling fan 160 is to be operated.

Typically, the activation of the cooling fan 140 is controlled in the sense of controlling the driving of the cooling fan 140, e.g., controlling whether a motor is actively driving the rotation. Accordingly, when the control system 140 deactivates the cooling fan 160, the cooling fan 160 typically does not directly stop spinning: when spinning at a regular rotation frequency, the cooling fan 160 may continue spinning after being deactivated, for example, for at least 2, at least 5, or at least 10 seconds.

Control system 140 may be configured to, at some point, operate the cooling fan 160 at a regular rotation frequency. For example, the regular rotation frequency may be a fixed rotation frequency used when the motion detector 150 is not being used and cooling is needed (as determined, e.g., using a temperature sensor). The regular rotation frequency can also be time-varying, for example, control system 140 may be configured to operate the cooling fan at a regular but time-varying rotation frequency depending on a measured temperature or on a current setting of the light-emitting element 170.

The regular rotation frequency however may cause an interference of the cooling fan with frequency differences established by the motion detector 150. Thus, noise may show up in the measured frequency range of the motion detector and either cause false positives or necessitate operating the motion detector 150 at a lower sensitivity. Interestingly, control system 140 may obtain a signal indicative of the motion detector 150 being used to detect motion, and control the cooling fan 160 based at least in part on this signal. By adjusting the activation and/or the rotation frequency of the cooling fan 160 if the signal indicates that the motion detector 150 is being used, interference of the cooling fan 160 with the frequency differences established by the motion detector 150 may be reduced. Detailed examples of performing this adjustment are described throughout this specification.

In some embodiments, the signal indicative of the activity of the motion detector is received from the motion detector 150. Accordingly, control system 140 may comprise a communication interface (not shown) arranged for communication with the motion detector 150 to receive the signal from the motion detector 150. In other embodiments, control system 140 is itself configured to control motion detector 150 and accordingly generates the signal. Also in this case, control system 140 may comprise a communication interface arranged through which the signal is communicated with the motion detector 150, the signal in this case being sent instead of received however. Instead of or in addition to enabling or disabling the motion detector 150, the controlling may also comprise controlling one or more operation parameters of the motion detector, such as a sensitivity value for the motion detection. Any suitable communication interfaces can be used, e.g., a bus or a wireless communication interface. The communication interface can be digital, e.g., to pass control parameters, or analogue, e.g., a power signal that is or is not provided to the motion detector 150.

Control system 140 may also be configured to control the activation of light-emitting element 170, e.g., to enable or disable the light-emitting element and/or to adjust a brightness. For example, control system 140 may be configured to control the activation of the light-emitting element 170, e.g., by switching on the light-emitting element 170 upon motion being detected by the motion detector 150 and/or switching off the light-emitting element 170 upon no motion being detected by the motion detector 150 during a hold time. Similarly to the communication with the motion detector, any suitable conventional digital or analogue communication interface for communication with the light-emitting element 170 may be used.

FIG. 1b schematically shows an example of an embodiment of a fan control system. In this embodiment, fan control system 141 is integrated, together with cooling fan 151 and motion detector 161, into luminaire 101. Luminaire 101 can for example be a high-bay fixture. Lights, especially LED lights, to be connected to such a high-bay fixture typically need cooling, and accordingly, cooling fan 151 may be provided. The light-emitting element 171 to be cooled by cooling fan 151, may be integrated into a lamp 111. In this case, lamp 111 is detachably connectable to luminaire 101. Lamp 111 can also be integrated into luminaire 101. The various components, e.g., the fan control system, cooling fan, and/or motion detector, may be adapted from their respective implementations in FIG. 1a.

As the skilled person understands, apart from the configurations of FIG. 1a and FIG. 1b, also various other configurations can be envisaged, e.g., a configuration in which the fan and fan control system are integrated in the lamp and the motion detector in the luminaire, and the other way around. The fan can also be detachably connected to the lamp, e.g., sold separately from the lamp, for example, with the fan control system being integrated into the lamp or luminaire. Variations will be apparent to the skilled person.

FIG. 1c schematically shows an example of an embodiment of a fan control system integrated into a smart pole 122. A smart pole in this case is a pole with a monitoring system 132 installed into it. The monitoring system 132 may comprise a motion detector 152 and a communication base station 182, e.g., for 4G or 5G communication or similar. The base station 182 may use radios and/or other components that dissipate a relatively large amount of heat, e.g., 400 W or more, and may accordingly require cooling, to which end cooling fan 162 may be installed. The cooling may be controlled by control system 142, which may also be used to control the motion detector. The different components, e.g., the control system, cooling fan, and motion detector, may be adapted from their respective implementations in FIG. 1a.

Although smart pole 122 typically also comprises a luminaire 102, this is not necessary for control system 142 to operate, and in particular, the fan 162 in this example is not used to cool the luminaire 102.

FIG. 1d and FIG. 1e provide a bottom view and a side view of a luminaire 103 into which light-emitting elements are integrated. For example, luminaire 103 may be based on luminaire 100 or 101 as discussed with respect to FIG. 1a and FIG. 1b.

As shown in the figures, luminaire 103 comprises a plurality of light-emitting elements 173-1, 173-2, up to 173-8. For illustration purposes, 8 light-emitting elements are shown in a circular configuration, but it is also possible to have a larger or a fewer number of light-emitting elements, and/or to put the light-emitting elements in a different configuration. A cooling fan 163 is provided, in this example on top of the luminaire, to provide cooling for the light-emitting elements. A motion sensor 153 is provided, in this example, at the bottom of the luminaire. Accordingly, for example, luminaire 103 may be suitable for mounting on or suspending from a ceiling. Luminaire 103 also comprises a control system (not shown) for controlling cooling fan 163, and optionally also motion detector 153 and/or the light-emitting elements.

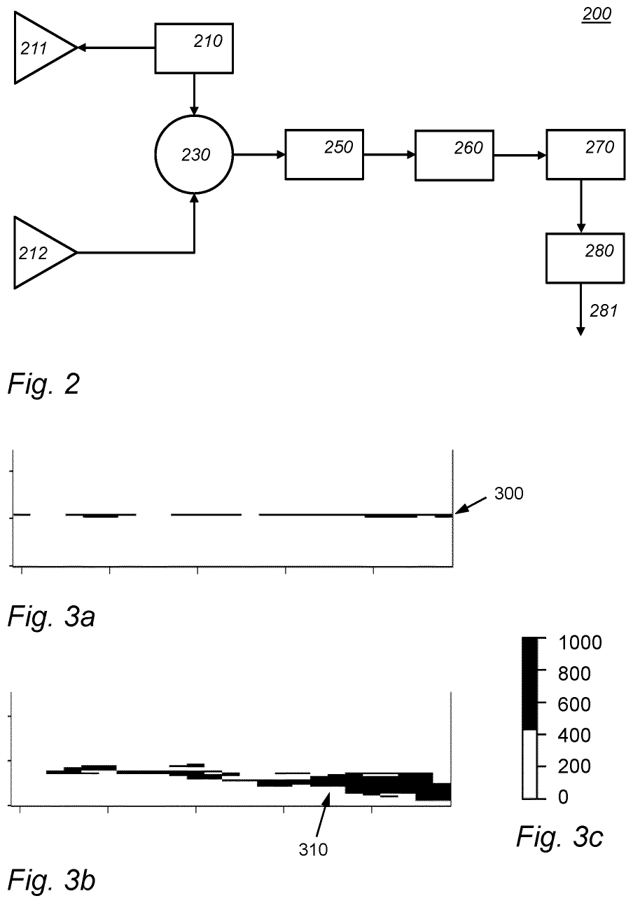

FIG. 2 schematically shows an example of an embodiment of a motion detector. FIG. 2 shows functional units that may be functional units of a processor circuit of the motion detector 200. For example, FIG. 2 may be used as a blueprint of a possible functional organization of the processor circuit.

Motion detector 200 may be configured to detect motion by emitting and receiving electromagnetic radiation and establishing frequency differences between the emitted and received electromagnetic radiation. Such a motion detector may be referred to as a Doppler-type motion detector. Specifically, the motion detector may use microwave radiation. Such motion detectors are also known as microwave sensors.

In this figure, an example is given of a single-channel motion detector, but many alternative implementations of motion detectors, e.g., also dual-channel motion detectors, are possible that are based on the same principles, e.g., that also apply a low-pass filter and/or a sampler. Below, it will be described how the motion detector 200 can detect movement based on the Doppler effect. Such motion detection may be combined, for example, with measurements of a direction of motion (e.g., by using a dual-channel motion detector) or a distance of the moving object (e.g., by using frequency shift keying), as is known in the art per se.

Shown in the figure is a transmission signal generator 210 configured to generate a signal, e.g., a sinusoidal signal, for transmission through a transmitter 211. Transmitter 211 may transmit the signal as electromagnetic radiation, e.g., as a microwave signal. For example, the transmitted signal may have a frequency of from 5 to 30 GHz, and/or from 30-100 GHz, etc., lower or higher is also possible. Examples of signal frequencies include: 5.8 GHz, 24 GHz, and 60 GHz. For example, the transmitted signal may have a frequency in the super high frequency band (SHF) or Extremely high frequency band (EHF).

The transmitted signal reflects off objects in the environment of the motion detector. The reflections are received in a receiver 212. Frequency differences between the emitted and received electromagnetic radiation are related to the speed, with respect to the motion detector, of moving objects that reflected the transmitted signal. Such frequency shifts are also known as Doppler shifts.

Further shown is a mixer 230. Mixer 230 may be configured to mix the transmitted signal with the received signal. Mixer 230 is typically implemented in hardware for efficiency reasons. Mathematically speaking, such mixing may correspond to a multiplication of the two signals. The output signal of the mixer may accordingly comprise frequency components corresponding to frequency differences between the emitted and received electronic radiation.

Accordingly, a signal representing frequency differences between emitted and received radiation (for example, generated using transmission signal generator 210, transmitter 211, receiver 212, and mixer 230 as shown in the figure, although this is not needed) may be obtained and subjected to a low-pass filter 250. The low-pass filter may be configured to filter out, meaning to substantially decrease the amplitude of, frequency components of the signal above given cut-off frequency. The low-pass filter is typically implemented in hardware and is in many cases not ideal, e.g., higher frequency components may still be somewhat present in the output signal of the low-pass filter.

Also shown is a sampler 260. Sampler may be configured to sample a signal representing the frequency differences, e.g., the signal output by the low-pass filter 250. Sampler 260 may operate at a given sampling rate which is typically two times the required Nyquist frequency. The Nyquist frequency is typically determined by the application. E.g., when addressing an application in which the maximum speed relative to a 5.8 GHz sensor is 2 m/s, then the maximum frequency is about 77 Hz. In order to measure such frequencies the Nyquist frequency is preferably at least 77 Hz, meaning that the sampling frequency is preferably minimally 154 Hz. Typically, the sampling rate can be at least 100 Hz and/or at least 1000 Hz, for example, 100 Hz, 120 Hz, or 1000 Hz. The sampling rate/Nyquist frequency of the sampler may be configurable. The cut-off frequency of the low-pass filter 250 may be set to be approximately equal to the Nyquist frequency of the sampler 260.

As is known, frequency components that are lower than the Nyquist frequency may be uniquely reconstructed by sampler 260 while frequency components higher than the Nyquist frequency may cause aliasing problems. For example, with a Nyquist frequency of 50 Hz, a frequency component of an incoming signal at 110 Hz may show up in the sampled signal at 110−2*50=10 Hz or 3*50−110=40 Hz.

The motion detector may further comprise a frequency domain converter 270 configured to convert a received signal, e.g., the signal output by the sampler 260, from a time domain to a frequency domain. For example, converter 270 may perform a Fourier transformation, e.g., a Discrete Fourier transform (DFT). The frequency-domain data output by converter 270 may contain multiple frequency bins for respective frequencies (more precisely, small frequency intervals). The frequencies may accordingly represent a measurement of frequency differences of the emitted and received electromagnetic radiation, and thus, by the Doppler effect, of velocities (or more precisely, small intervals of velocities) of moving objects reflecting the electromagnetic radiation. For each frequency bin, an amplitude may be determined, e.g. a Fourier coefficient, indicating a strength of the frequency in the signal. Such an amplitude may be referred to as an energy of a frequency bin.

For example, one frequency bin may represent the frequency range from 40-42 Hz. The frequency range corresponding to a frequency bin may be, e.g., about 2 Hz, or more, or less, say in the range from 0.5 to 5 Hz. A magnitude for a frequency bin may be taken as the absolute value of the amplitude. In an embodiment, the signal-processing may be configured to detect motion components within a time period or time slice. The time-period may be, say, a second, a half-second, etc. In an embodiment, the time period is less than 30 seconds.

For example, a frequency conversion may be performed each time after a pre-determined number of time-domain samples have been obtained. For example, every 24 time-domain samples a frequency domain conversion may be performed. For example, in an embodiment, a 5.8 GHz sensor, is combined with 24 time-samples per time-slice.

For example, one can sample at 250 Hz, and take for every 24 new samples an FFT with a length of 128 points. In this case the FFTs are overlapping. For light switching one preferably reports motion quickly, e.g., in 0.5 s. With the example above one has a few FFT for making the decision. For other situations, one can take more time: for example, when trigger on motion when the light is already on, or for occupancy detection.

Given a frequency domain representation of the frequency differences between the emitted and received electromagnetic radiation, a filter 280 may be applied to establish frequency differences 281 considered to correspond to actual moving objects and not, e.g., to measurement artefacts, noise, etc. Filter 280 typically acts at a certain sensitivity. E.g., only if an amplitude at a certain frequency exceeds a given sensitivity threshold, a motion is detected with a velocity corresponding to that frequency. In other words, a filter 280 with low sensitivity may apply a high threshold to conclude that there is a moving object, and, the other way around, filter 280 can be made more sensitive by lowering the threshold. Filter 280 may automatically determine the threshold to be applied based on a noise level of its incoming signal, for example, the threshold may be set to a value of at least two times the noise level, e.g., three times the noise level. Typically, the sensitivity of the filter 280, and thereby of the motion detector 200, is configurable, e.g., the sensitivity threshold itself may be set or the way it depends on the noise level.

Thresholds to be applied may differ per frequency interval, e.g., a different threshold may be applied for lower frequency differences than for higher frequency differences. Accordingly, operating the motion detector 200 at a higher sensitivity or at a lower sensitivity, as used throughout this specification, may mean applying a lower respectively a higher threshold for at least some of the frequency differences detected by the motion detection.

At the edges of range of measured frequency differences, e.g., at the higher and lower bins some special considerations may be needed. For example, at the lower end of frequencies measurements turn out to be often unreliable. In an embodiment, frequency bins below a frequency floor are estimated as cause by noise. For example, the noise frequency floor may be less than 9.3 Hz for a 5.8 GHz sensor. These low frequencies are found to have more spurious signals and are therefore not reliable and consistent. The frequency floor may increase with the frequency of the sensor for a Doppler sensor.

Given a set of frequency differences established to correspond to moving objects, the motion detector 200 may report this motion information in various ways. For example, the motion detector may provide a signal indicating whether or not motion is detected, for example, a binary yes/no value or a value indicating a likelihood of motion.

The motion detector may also report a velocity or a set of velocities that have been detected. For example, based on the Doppler effect, such velocities may be determined by applying the relation

$${f}_{r} - {f}_{t} = 2 v \frac{{f}_{t}}{c - v}$$

or its approximation

$${f}_{r} - {f}_{t} \approx 2 v \frac{{f}_{t}}{c} ,$$

where fᵣ is the frequency of emitted radiation; fᵣ is the frequency of received radiation; v is the velocity of the moving object; and c is the speed of light.

According to the above relations, the set of velocities that can be measured may depend on the set of frequency differences that can be measured and/or on the emitted frequencies. Accordingly, parameters of the various components of the motion detector 200 may be selected to enable velocities in a range of interest to be determined. For example, this can apply to the cut-off frequency of an applied low-pass filter 250 and/or the sampling frequency of an applied sampler 260. It is noted that the measured velocities represent velocities with respect to the motion detector, e.g., velocity components in the direction of the motion detector. Accordingly, the range of relevant velocities may for example include a typical moving speed of a person at 4 km/h, but also smaller values possibly corresponding to a person who is not walking directly towards or away from the motion detector, etcetera.

FIG. 3a-3c show examples of spectrograms of a signal of a motion detector. The signals shown are the output of an FFT transform, e.g., as determined by frequency domain converter 270 of FIG. 2. FIG. 3a and FIG. 3b show two spectrograms. The horizontal axis represents time. In this case, 25 measurements were made each lasting 100 ms. The vertical axis shows 64 FFT bins representing respective measured frequency differences. The intensity shown indicates the amplitude measured at a certain frequency at a certain time. Amplitudes above a given threshold are shown, according to the scale shown in FIG. 3c.

The spectrogram in FIG. 3a represents motion detector measurements in a room where there was no motion. As may be expected, at most frequencies, a low amplitude is measured. However, around the 25th frequency bin, a noise 300 is visible. The noise is a few FFT bins wide, as may be expected of a fan. The amplitude at which the noise occurs is reasonably high, e.g., the noise may well be mistaken for motion.

Accordingly, it is beneficial to avoid this noise from occurring in this signal. For example, by disabling the fan or changing the frequency to a frequency out of the range of the motion detector, noise 300 may be expected to disappear. However, also by periodically changing the rotation frequency of the cooling fan, a corresponding periodical change may be expected in the frequency at which noise 300 may appear. Since the noise 300 is confined to a few frequency bins, it is feasible to isolate and ignore it.

The spectrogram in FIG. 3b represents motion detector measurements in a room where actual measurements were taking place. In this case, there is a relatively wide band 310 of noise that also varies significantly along the time dimension. Although this figure suggests that it may be hard to filter out a noise signal such as signal 300 in case there is also a motion signal 310, this does not have to be a problem since, if there is motion anyway, the failure to filter out noise does not lead to a false positive in terms of whether or not noise is present.

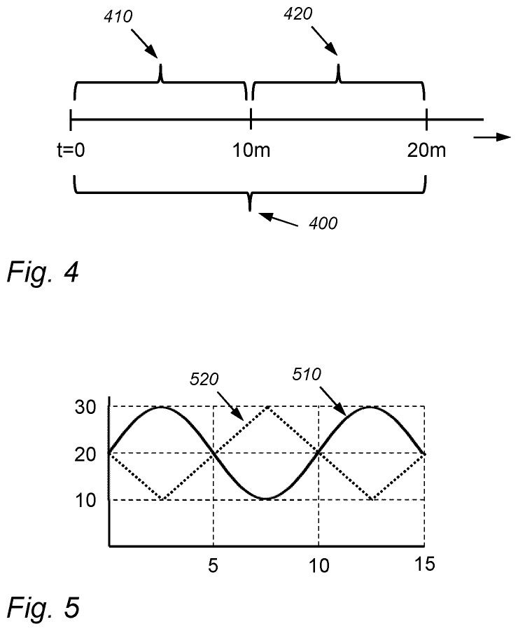

Returning to FIGS. 1a-1c and also referring to FIGS. 4-5, several specific examples are now discussed in which the activation and/or the rotation frequency of a cooling fan are adjusted in response to a motion detector being in use.

### Example 1

In this example, the rotation frequency of the cooling fan is temporarily increased. This example can be applied, for example, in a high lumen lamp with an integrated fan and a motion detector based on microwave radiation.

As a concrete example, the motion detector can use a 5.8 GHz continuous wave for sensing. During times in which the sensor is sensing for motion, the driving speed of the fan may be adapted to reduce noise on the microwave signal. In this example, the motion detector may employ a low pass filter filtering out frequencies above 120 Hz. Accordingly, the rotation frequency may be temporarily adjusted, while the motion detector is active, to a value above 120 Hz.

Note that the increased rotation frequency is applied only temporarily. This has several advantages over using a fan that continuously operates at 120 Hz, for example, improved lifetime, and reduced audible noise and power consumption. The time during which the rotation frequency is increased can for example be in in the range of seconds, e.g., at most or at least 1, 2, or 5 seconds; or in the range of minutes, e.g., at most or at least 5, 10, or 20 minutes.

### Example 2

This example is the same as Example 1, but the rotation frequency in this example is chosen in dependence on the Nyquist frequency/sampling frequency at which the motion detector samples the frequency differences. In this example, the sampling frequency of the microwave signal is 300 Hz. In this case, the fan speed may be set to 600 Hz. Generally, any integer multiple of the Nyquist frequency can be chosen. The benefit of using an integer multiple of the sampling frequency is that disturbances are easier to handle in the algorithms.

Apart from integer multiples, it is also beneficial to select integer fractions. For example, the fan speed may be set to 50 Hz. This is because, apart from the fan frequency itself, also integer multiples of it may show up in the frequency measurements. By selecting the fan frequency to be a fraction of the Nyquist frequency, e.g., one half, one third, two-thirds, etc., at least multiples of the fan frequency may become multiples of the Nyquist frequency and may accordingly become easier to handle.

### Example 3

In this example, the fan and the motion detector are part of a lighting system (e.g., integrated into a luminaire or lamp) that is controlled based on motion being sensed by the motion detector. This example can involve e.g. a high lumen luminaire with an integrated motion detector based on microwave radiation, e.g., using a frequency of 24 GHz. When the lamp is off (in other words, when the light-emitting element disabled), the fan is chosen to be off as there is nothing to cool. During this phase the microwave signal has a good sensitivity, e.g., its sensitivity can be set to a high value, or it may be automatically high if it is determined e.g., based on a noise level. If motion is detected, the lamp may be turned on (in other words, the light-emitting element enabled) automatically, but this is not necessary.

As also illustrated in FIG. 4, when the lamp is on, the motion detector may be used to turn off the light after a predefined period 400 of not detecting motion. The length of this predefined period, sometimes referred to as the hold time, can for example be somewhere between 1 minute and an hour; for example, common settings include 3, 10 and 20 minutes. Accordingly, when the light is on, motion detection is needed e.g. to check if a person is present. However, if the light is on, also cooling may be needed, which may disturb the motion detection.

In this example, during a first part 410 of the predefined period, the motion detector is configured to continuously sense motion. During this period, the motion detector operates at a first sensitivity, which may be set relatively low explicitly or implicitly (e.g., based on noise levels), in order to reduce the probability of false positives due to the cooling fan. Some motion may be missed.

Once the motion detector has not received any triggers for some time, for example, between 25% and 75% of the hold time, e.g., half the hold time, a second part 420 of the predefined time period 400 may be entered in which the activation and/or the rotation frequency of the cooling fan may be adapted as described herein, for example, by deactivating the cooling fan or operating the cooling fan at a higher frequency. This may reduce interference with the motion detector, which can accordingly be configured, explicitly or implicitly (e.g., based on noise levels) to operate at a higher sensitivity. Accordingly, the likelihood of missing an actual motion is lowered during this second part of the predefined time period, so that e.g. the chance that the lights are turned off while somebody is present, is reduced. Still, it is avoided to have to adjust the operation of the cooling fan from its regular rotation frequency also during the first part 410 of the predefined time period.

Whenever during period 400, 410, and/or 420, motion is detected, the time periods may be reset, e.g., period 400 starts again. When no motion is detected during the whole period 400, the light may be turned off.

The cooling fan may be deactivated during the second part 420 of the predefined period. This may introduce the risk that temperature in the luminaire get too high. This can be mitigated, e.g., by dimming the light: this dimming can be performed always or depending on actually measuring a too high temperature with a temperature sensor.

### Example 4

This example is the same as example 3, but in this case, during second part 420 of the predefined period, the system alternates between activating the cooling fan while deactivating the motion detector; and activating the motion detector while deactivating the cooling fan. For example, the motion detector can be enabled for at least one and at most five seconds, for example, two seconds. Also the cooling fan can be driven, for example, for at least one and at most five seconds, for example two seconds. The periods of doing motion detection and driving the fan need not be the same, however. Accordingly, nearly continuous cooling may be combined with nearly continuous sensing. It is noted that during periods in which the cooling fan is not driven, although the fan engine is switched off, the fan itself may still be rotating and thus still provide some degree of cooling. For example, a fan may be used that, when it is driven at its regular rotation frequency and its driving is then stopped, continues to rotate for at least two, at least five, or at least ten seconds.

### Example 5

In this example, the rotation frequency of the cooling fan is adjusted according to a periodic waveform. As a concrete example, consider a cooling fan with a frequency of 20 Hz. If a motion detector is used with a carrier microwave frequency of 5.8 GHz, then a frequency of 20 Hz corresponds to a Doppler speed of about 50 cm/s. In various use cases this speed lies within the range of interest.

In this example, the rotation frequency of the fan is not kept constant at 20 Hz but varied according to a periodic waveform, in this case centered around 20 Hz. Two example waveforms are shown in FIG. 5. Line 510 demonstrates a sinusoidal waveform centered around 20 Hz with a period of 10 seconds and an amplitude of 10 Hz, e.g.,

$${frequency}_{fan} ( t in seconds ) = 20 Hz + 10 Hz * sin ( \frac{2 π}{10} t ) .$$

Various other types of periodic waveforms, such a triangular waveform 520, are also possible however. The period can be chosen, for example, to be at least five seconds and at most 30 seconds, for example 10 seconds. Choosing the period sufficiently long allows for more reliable detection of the waveform by the motion detector, while not choosing the period for too long allows the waveform to be detected still sufficiently quickly.

The motion detector may be configured to filter out frequency differences between the emitted and received electromagnetic variations that vary according to the periodic waveform.

For example, the motion detector may be configured to filter out the fan frequency (e.g., plus or minus 1 FFT bin, depending on sampling frequencies and time window in FFT). As the frequency of the fan varies, various frequencies of the waveform employed by the cooling fan can be measured, although not at each moment in time.

Interestingly, instead of, or in addition to, the exact frequency of the cooling fan, the motion detector can also filter out other frequencies that vary according to the periodic waveform. For example, interference can also take place at half or double the cooling fan frequency. If a frequency signal, despite not being at the frequency of the cooling fan, still varies substantially according to the waveform, e.g., at least with the same period and/or phase, it can still be filtered out as being caused by the cooling fan.

It is noted that it is also possible to more generally vary the frequency of the cooling fan between multiple frequencies, e.g., it is not absolutely necessary to use a periodic waveform. For example, the frequency could in principle be varied arbitrarily, with the frequency difference corresponding to the currently used frequency being filtered out by the motion detector. This also helps to reduce inference, but the use of a periodic waveform is preferred since it also allows to detect inference patterns that do not occur exactly at this frequency by detecting the shape of the waveform as opposed to filtering out any particular frequency.

### Example 6

This example can be combined with the previous examples. In this example, the sensitivity of the motion detector may be decreased when the cooling fan is active. As also discussed with respect to FIG. 2, various motion detectors use signal processing algorithms with a controllable sensitivity threshold. Since activity of the cooling fan may lead to false positives, in this example, the threshold is increased (and, as a consequence, the sensitivity is decreased), during times where the fan is operated.

Typically, control systems 140-142 and/or motion detectors 150-152 each comprise a microprocessor which executes appropriate software stored at these devices; for example, that software may have been downloaded and/or stored in a corresponding memory, e.g., a volatile memory such as RAM or a non-volatile memory such as Flash. Alternatively, the devices may, in whole or in part, be implemented in programmable logic, e.g., as field-programmable gate array (FPGA). The devices may be implemented, in whole or in part, as a so-called application-specific integrated circuit (ASIC), e.g., an integrated circuit (IC) customized for their particular use. For example, the circuits may be implemented in CMOS, e.g., using a hardware description language such as Verilog, VHDL, etc.

In an embodiment, a control system comprises one or more electronic circuits. The circuits may be a processor circuit and storage circuit, the processor circuit executing instructions represented electronically in the storage circuits. A processor circuit may be implemented in a distributed fashion, e.g., as multiple sub-processor circuits. A storage may be distributed over multiple distributed sub-storages. Part or all of the memory may be an electronic memory, magnetic memory, etc. For example, the storage may have volatile and a non-volatile part. Part of the storage may be read-only.

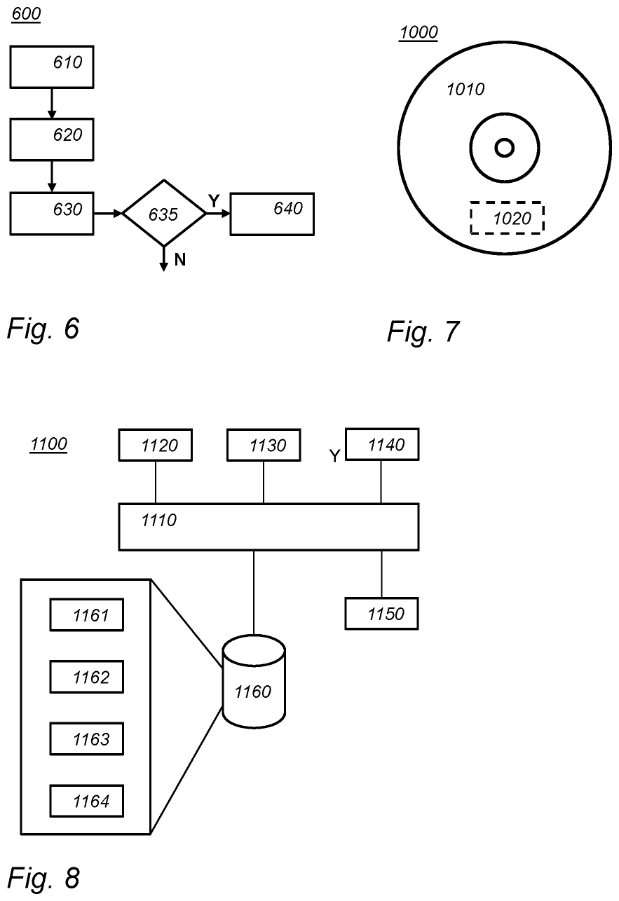

FIG. 6 schematically shows an example of an embodiment of a method 600 of controlling a cooling fan. The controlling may comprise controlling an activation and/or a rotation frequency of the cooling fan. Method 600 may comprise:

arranging 610 communication with a motion detector, the motion detector being configured to detect motion by emitting and receiving electromagnetic radiation and establishing frequency differences between the emitted and received electromagnetic radiation;

operating 620 the cooling fan at a regular rotation frequency;

obtaining 630 a signal indicative of the motion detector being used to detect motion;

in response 635 to said signal indicating that the motion detector is being used, adjusting 640 the activation and/or the rotation frequency of the cooling fan, wherein said adjustment reduces an interference of the cooling fan with the frequency differences established by the motion detector.

Many different ways of executing the method are possible, as will be apparent to a person skilled in the art. For example, the steps can be performed in the shown order, but the order of the steps may also be varied or some steps may be executed in parallel. Moreover, in between steps other method steps may be inserted. The inserted steps may represent refinements of the method such as described herein, or may be unrelated to the method. For example, steps 610, 620 may be executed, at least partially, in parallel. Moreover, a given step may not have finished completely before a next step is started.

Embodiments of the method may be executed using software, which comprises instructions for causing a processor system to perform method 600. Software may only include those steps taken by a particular sub-entity of the system. The software may be stored in a suitable storage medium, such as a hard disk, a floppy, a memory, an optical disc, etc. The software may be sent as a signal along a wire, or wireless, or using a data network, e.g., the Internet. The software may be made available for download and/or for remote usage on a server. Embodiments of the method may be executed using a bitstream arranged to configure programmable logic, e.g., a field-programmable gate array (FPGA), to perform the method.

It will be appreciated that the invention also extends to computer programs, particularly computer programs on or in a carrier, adapted for putting the invention into practice. The program may be in the form of source code, object code, a code intermediate source, and object code such as partially compiled form, or in any other form suitable for use in the implementation of an embodiment of the method. An embodiment relating to a computer program product comprises computer executable instructions corresponding to each of the processing steps of at least one of the methods set forth. These instructions may be subdivided into subroutines and/or be stored in one or more files that may be linked statically or dynamically. Another embodiment relating to a computer program product comprises computer executable instructions corresponding to each of the means of at least one of the systems and/or products set forth.

FIG. 7 shows a computer readable medium 1000 having a writable part 1010 comprising a computer program 1020, the computer program 1020 comprising instructions for causing a processor system to perform a motion detection method, according to an embodiment. The computer program 1020 may be embodied on the computer readable medium 1000 as physical marks or by means of magnetization of the computer readable medium 1000. However, any other suitable embodiment is conceivable as well. Furthermore, it will be appreciated that, although the computer readable medium 1000 is shown here as an optical disc, the computer readable medium 1000 may be any suitable computer readable medium, such as a hard disk, solid state memory, flash memory, etc., and may be non-recordable or recordable. The computer program 1020 comprises instructions for causing a processor system to perform said method of controlling a cooling fan.

FIG. 8 illustrates an exemplary hardware diagram 1100 for implementing a device according to an embodiment. As shown, the device 1100 includes a processor 1120, memory 1130, user interface 1140, communication interface 1150, and storage 1160 interconnected via one or more system buses 1110. It will be understood that this figure constitutes, in some respects, an abstraction and that the actual organization of the components of the device 1100 may be more complex than illustrated.

The processor 1120 may be any hardware device capable of executing instructions stored in memory 1130 or storage 1160 or otherwise processing data. As such, the processor may include a microprocessor, field programmable gate array (FPGA), application-specific integrated circuit (ASIC), or other similar devices. For example, the processor may be an Intel Core i7 processor, ARM Cortex-R8, etc. In an embodiment, the processor may be ARM Cortex M0.

The memory 1130 may include various memories such as, for example L1, L2, or L3 cache or system memory. As such, the memory 1130 may include static random-access memory (SRAM), dynamic RAM (DRAM), flash memory, read only memory (ROM), or other similar memory devices. It will be apparent that, in embodiments where the processor includes one or more ASICs (or other processing devices) that implement one or more of the functions described herein in hardware, the software described as corresponding to such functionality in other embodiments may be omitted.

The user interface 1140 may include one or more devices for enabling communication with a user such as an administrator. For example, the user interface 1140 may include a display, a mouse, and a keyboard for receiving user commands. In some embodiments, the user interface 1140 may include a command line interface or graphical user interface that may be presented to a remote terminal via the communication interface 1150.

The communication interface 1150 may include one or more devices for enabling communication with other hardware devices. For example, the communication interface 1150 may include a network interface card (NIC) configured to communicate according to the Ethernet protocol. For example, the communication interface 1150 may comprise an antenna, connectors or both, and the like. Additionally, the communication interface 1150 may implement a TCP/IP stack for communication according to the TCP/IP protocols. Various alternative or additional hardware or configurations for the communication interface 1150 will be apparent.

The storage 1160 may include one or more machine-readable storage media such as read-only memory (ROM), random-access memory (RAM), magnetic disk storage media, optical storage media, flash-memory devices, or similar storage media. In various embodiments, the storage 1160 may store instructions for execution by the processor 1120 or data upon with the processor 1120 may operate. For example, the storage 1160 may store a base operating system 1161 for controlling various basic operations of the hardware 1100. For example, the storage may store instructions 1162-1164 for operating the cooling fan at a regular rotation frequency; for obtaining a signal indicative of the motion detector being used to detect motion; and for, in response to said signal indicating that the motion detector is being used, adjust the activation and/or the rotation frequency of the cooling fan, wherein said adjustment reduces an interference of the cooling fan with the frequency differences established by the motion detector. The storage may also store instructions for controlling the motion detector and/or performing the motion detection.

It will be apparent that various information described as stored in the storage 1160 may be additionally or alternatively stored in the memory 1130. In this respect, the memory 1130 may also be considered to constitute a “storage device” and the storage 1160 may be considered a “memory.” Various other arrangements will be apparent. Further, the memory 1130 and storage 1160 may both be considered to be “non-transitory machine-readable media.” As used herein, the term “non-transitory” will be understood to exclude transitory signals but to include all forms of storage, including both volatile and non-volatile memories.

While device 1100 is shown as including one of each described component, the various components may be duplicated in various embodiments. For example, the processor 1120 may include multiple microprocessors that are configured to independently execute the methods described herein or are configured to perform steps or subroutines of the methods described herein such that the multiple processors cooperate to achieve the functionality described herein. Further, where the device 1100 is implemented in a cloud computing system, the various hardware components may belong to separate physical systems. For example, the processor 1120 may include a first processor in a first server and a second processor in a second server.

It should be noted that the above-mentioned embodiments illustrate rather than limit the invention, and that those skilled in the art will be able to design many alternative embodiments.

In the claims, any reference signs placed between parentheses shall not be construed as limiting the claim. Use of the verb ‘comprise’ and its conjugations does not exclude the presence of elements or steps other than those stated in a claim. The article ‘a’ or ‘an’ preceding an element does not exclude the presence of a plurality of such elements. Expressions such as “at least one of” when preceding a list of elements represent a selection of all or of any subset of elements from the list. For example, the expression, “at least one of A, B, and C” should be understood as including only A, only B, only C, both A and B, both A and C, both B and C, or all of A, B, and C. The invention may be implemented by means of hardware comprising several distinct elements, and by means of a suitably programmed computer. In the device claim enumerating several means, several of these means may be embodied by one and the same item of hardware.

In the claims references in parentheses refer to reference signs in drawings of exemplifying embodiments or to formulas of embodiments, thus increasing the intelligibility of the claim. These references shall not be construed as limiting the claim.

1. A luminaire, comprising: a control system, a cooling fan and motion detector; wherein the cooling fan is arranged to cool a light-emitting element connectable to or integrated in the luminaire, and wherein the control system is arranged for controlling the cooling fan, said controlling comprising controlling an activation and/or a rotation frequency of the cooling fan, the control system comprising:
a communication interface arranged for communication with motion detector, the motion detector being configured to detect motion by emitting and receiving electromagnetic radiation and establishing frequency differences between the emitted and received electromagnetic radiation;
a processor subsystem configured to:
operate the cooling fan at a rotation frequency;
obtain a signal indicative of the motion detector being used to detect motion;
in response to said signal indicating that the motion detector is being used, adjust the activation and/or the rotation frequency of the cooling fan, wherein said adjustment reduces an interference of the cooling fan with the frequency differences established by the motion detector.

2. The luminaire of claim 1, wherein the control system is further configured to control the motion detector.

3. The luminaire of claim 2, wherein the processor subsystem is configured to alternate between activating the cooling fan while deactivating the motion detector; and activating the motion detector while deactivating the cooling fan.

4. The luminaire of claim 2, further configured to control an activation of a light-emitting element, comprising disabling the light-emitting element after a predefined period of not detecting motion; the processor subsystem being configured to:
during a first part of the predefined period, operate the motion detector at a first sensitivity;
during a second part of the predefined period, adjust the activation and/or the rotation frequency of the cooling fan, and operate the motion detector at a second sensitivity higher than the first sensitivity.

5. The luminaire of claim 4, wherein the processor subsystem is configured to, during the second part of the predefined period, deactivate the cooling fan and dim the light-emitting element.

6. The luminaire of claim 2, wherein the processor subsystem is configured to, when the cooling fan is active, decrease a sensitivity of the motion detector.

7. The luminaire of claim 1, wherein the processor subsystem is configured to adjust the activation and/or the rotation frequency of the cooling fan by temporarily deactivating the cooling fan.

8. The luminaire of claim 7, wherein the control system is configured to deactivate the cooling fan by deactivating driving of the cooling fan, but wherein the control system does not prevent the cooling fan from spinning.

9. The luminaire of claim 1, wherein the motion detector is configured to apply a low-pass filter to a signal representing the frequency differences between the emitted and received electromagnetic radiation, the processor subsystem being configured to adjust the activation and/or the rotation frequency of the cooling fan by temporarily increasing the rotation frequency to at least a cut-off frequency of the low-pass filter.

10. The luminaire of claim 1, wherein the motion detector is configured to sample a signal representing the frequency differences, the processor subsystem being configured to adjust the activation and/or the rotation frequency of the cooling fan by temporarily increasing the rotation frequency to an integer fraction or multiple of the Nyquist frequency of said sampling.

11. The luminaire of claim 1, wherein the processor subsystem is configured to adjust the rotation frequency of the cooling fan according to a periodic waveform, the motion detector being configured to filter out frequency differences between the emitted and received electromagnetic variations that vary according to the periodic waveform.

12. A lamp, connectable to a luminaire and comprising: a control system, a cooling fan a motion detector, and a light-emitting element; wherein the cooling fan is arranged to cool the light-emitting element, and wherein the control system is arranged for controlling the cooling fan, said controlling comprising controlling an activation and/or a rotation frequency of the cooling fan, the control system comprising:
a communication interface arranged for communication with the motion detector, the motion detector being configured to detect motion by emitting and receiving electromagnetic radiation and establishing frequency differences between the emitted and received electromagnetic radiation;
a processor subsystem configured to:
operate the cooling fan at a rotation frequency;
obtain a signal indicative of the motion detector being used to detect motion;
in response to said signal indicating that the motion detector is being used, adjust the activation and/or the rotation frequency of the cooling fan, wherein said adjustment reduces an interference of the cooling fan with the frequency differences established by the motion detector.

13. The lamp according to claim 12, wherein the control system is further configured to control the motion detector.

14. A method of controlling a luminaire comprising a cooling fan arranged to cool a light-emitting element connectable to or integrated in the luminaire or of controlling a lamp comprising a light-emitting element and a cooling fan arranged to cool the light-emitting element, said controlling comprising controlling an activation and/or a rotation frequency of the cooling fan, the method comprising:
arranging communication with a motion detector, the motion detector being configured to detect motion by emitting and receiving electromagnetic radiation and establishing frequency differences between the emitted and received electromagnetic radiation;
operating the cooling fan at a regular rotation frequency;
obtaining a signal indicative of the motion detector being used to detect motion;
in response to said signal indicating that the motion detector is being used, adjusting the activation and/or the rotation frequency of the cooling fan, wherein said adjustment reduces an interference of the cooling fan with the frequency differences established by the motion detector.

15. A transitory or non-transitory computer readable medium comprising data representing instructions to cause a processor system to perform the method according to claim 14.
